(19) United States
(12) Patent Application Publication
(10) Pub. No.: US 2019/0174632 A1
(43) Pub. Date: Jun. 6, 2019

(54) FLEXIBLE PRINTED CIRCUIT AND ELECTRONIC DEVICE

(71) Applicant: CANON COMPONENTS, INC., Saitama-ken (JP)

(72) Inventor: Takaya SHUTO, Saitama-ken (JP)

(21) Appl. No.: 16/205,864

(22) Filed: Nov. 30, 2018

(30) Foreign Application Priority Data
Dec. 5, 2017 (JP) 2017-233610
Dec. 5, 2017 (JP) 2017-233611
Nov. 29, 2018 (JP) 2018-223937

(51) Int. Cl. H05K 3/10; H05K 1/11; H05K 3/42

(52) U.S. Cl. CPC H05K 3/108; H05K 1/118; H05K 1/115; H05K 2201/09727; H05K 2203/072; H05K 2203/0723; H05K 2201/098; H05K 3/423

(57) ABSTRACT

A flexible printed circuit according to the present invention comprises a flexible base, a wiring pattern arranged on the flexible base, and a via that is provided in the flexible base and is electrically connected to the wiring pattern, wherein the wiring pattern is formed to have an aspect ratio of at least 0.7 or more. This feature enables to increase the density of a wiring structure in the flexible printed circuit while improving the reliability thereof.

### BACKGROUND OF THE INVENTION

### Field of the Invention

The present invention relates to a flexible printed circuit and an electronic device.

### Description of the Related Art

Some electronic devices include a plurality of electronic components and a flexible printed circuit for connecting the electronic components, and as a result of such a configuration, electrical communication is possible between the electronic components. The flexible printed circuit includes a flexible base made of resin or the like, and wiring patterns, vias, and the like provided in the flexible base, for example (refer to Japanese Patent Laid-Open No. 2010-10413).

It is conceivable that the density of a wiring structure formed by wiring patterns, vias, and the like in the flexible printed circuit increases in correspondence to multi-functionalization of individual electronic components and an increase in the number of terminals in accordance therewith. Therefore, technology for realizing such a flexible printed circuit is required while improving its reliability.

The present invention provides a technology that is advantageous for increasing the density of a wiring structure in a flexible printed circuit while improving the reliability thereof.

### SUMMARY OF THE INVENTION

One aspect of the present invention relates to a flexible printed circuit, and the flexible printed circuit comprises a flexible base, a wiring pattern arranged on the flexible base, and a via that is provided in the flexible base and is electrically connected to the wiring pattern, wherein the wiring pattern is formed to have an aspect ratio of at least 0.7 or more.

Further features of the present invention will become apparent from the following description of exemplary embodiments with reference to the attached drawings.

### BRIEF DESCRIPTION OF THE DRAWINGS

FIG. 1A is a cross-sectional view for illustrating an example of a method of manufacturing a printed circuit board according to an embodiment.

FIG. 1B is a cross-sectional view for illustrating the example of the method of manufacturing a printed circuit board according to the embodiment.

FIG. 1C is a cross-sectional view for illustrating the example of the method of manufacturing a printed circuit board according to the embodiment.

FIG. 1D is a cross-sectional view for illustrating the example of the method of manufacturing a printed circuit board according to the embodiment.

FIG. 1E is a cross-sectional view for illustrating the example of the method of manufacturing a printed circuit board according to the embodiment.

FIG. 1F is a cross-sectional view for illustrating the example of the method of manufacturing a printed circuit board according to the embodiment.

FIG. 1G is a cross-sectional view for illustrating the example of the method of manufacturing a printed circuit board according to the embodiment.

FIG. 1H is a cross-sectional view for illustrating the example of the method of manufacturing a printed circuit board according to the embodiment.

FIG. 1I is a cross-sectional view for illustrating the example of the method of manufacturing a printed circuit board according to the embodiment.

FIG. 1J is a cross-sectional view for illustrating the example of the method of manufacturing a printed circuit board according to the embodiment.

FIG. 1K is a cross-sectional view for illustrating the example of the method of manufacturing a printed circuit board according to the embodiment.

FIG. 1L is a cross-sectional view for illustrating the example of the method of manufacturing a printed circuit board according to the embodiment.

FIG. 1M is a cross-sectional view for illustrating the example of the method of manufacturing a printed circuit board according to the embodiment.

FIG. 2 is a cross-sectional perspective view for illustrating an example of the wiring structure of a printed circuit board according to the embodiment.

FIG. 3A is a cross-sectional view for illustrating an example of the method of manufacturing a printed circuit board according to an embodiment.

FIG. 3B is a cross-sectional view for illustrating the example of the method of manufacturing a printed circuit board according to the embodiment.

FIG. 3C is a cross-sectional view for illustrating the example of the method of manufacturing a printed circuit board according to the embodiment.

FIG. 3D is a cross-sectional view for illustrating the example of the method of manufacturing a printed circuit board according to the embodiment.

FIG. 3E is a cross-sectional view for illustrating the example of the method of manufacturing a printed circuit board according to the embodiment.

FIG. 3F is a cross-sectional view for illustrating the example of the method of manufacturing a printed circuit board according to the embodiment.

FIG. 3G is a cross-sectional view for illustrating the example of the method of manufacturing a printed circuit board according to the embodiment.

FIG. 3H is a cross-sectional view for illustrating the example of the method of manufacturing a printed circuit board according to the embodiment.

FIG. 3I is a cross-sectional view for illustrating the example of the method of manufacturing a printed circuit board according to the embodiment.

FIG. 4 is a cross-sectional perspective view for illustrating an example of the wiring structure of a printed circuit board according to the embodiment.

FIG. 5A is a cross-sectional view for illustrating another example of the method of manufacturing a printed circuit board according to an embodiment.

FIG. 5B is a cross-sectional view for illustrating the other example of the method of manufacturing a printed circuit board according to the embodiment.

FIG. 5C is a cross-sectional view for illustrating the other example of the method of manufacturing a printed circuit board according to the embodiment.

FIG. 5D is a cross-sectional view for illustrating the other example of the method of manufacturing a printed circuit board according to the embodiment.

FIG. SE is a cross-sectional view for illustrating the other example of the method of manufacturing a printed circuit board according to the embodiment.

FIG. 5F is a cross-sectional view for illustrating the other example of the method of manufacturing a printed circuit board according to the embodiment.

FIG. 5G is a cross-sectional view for illustrating the other example of the method of manufacturing a printed circuit board according to the embodiment.

FIG. 5H is a cross-sectional view for illustrating the other example of the method of manufacturing a printed circuit board according to the embodiment.

FIG. 5I is a cross-sectional view for illustrating the other example of the method of manufacturing a printed circuit board according to the embodiment.

FIG. 6A1 is a schematic diagram for illustrating a cross-sectional shape of a wiring structure.

FIG. 6A2 is a schematic diagram for illustrating the cross-sectional shape of the wiring structure.

FIG. 6A3 is a schematic diagram for illustrating the cross-sectional shape of the wiring structure.

FIG. 6B 1 is a schematic diagram for illustrating a cross-sectional shape of a wiring structure.

FIG. 6B2 is a schematic diagram for illustrating the cross-sectional shape of the wiring structure.

FIG. 6B3 is a schematic diagram for illustrating the cross-sectional shape of the wiring structure.

### DESCRIPTION OF THE EMBODIMENTS

Hereinafter, suitable embodiments of the present invention will be described with reference to the attached drawings. Note that the drawings are merely schematic diagrams that are described for the purpose of illustrating structures or configurations, and the sizes of members shown in the drawings may be different from those of actual members. Also, in the drawings, the same members or the same constituent elements are given the same reference codes, and redundant descriptions will be omitted.

### First Embodiment

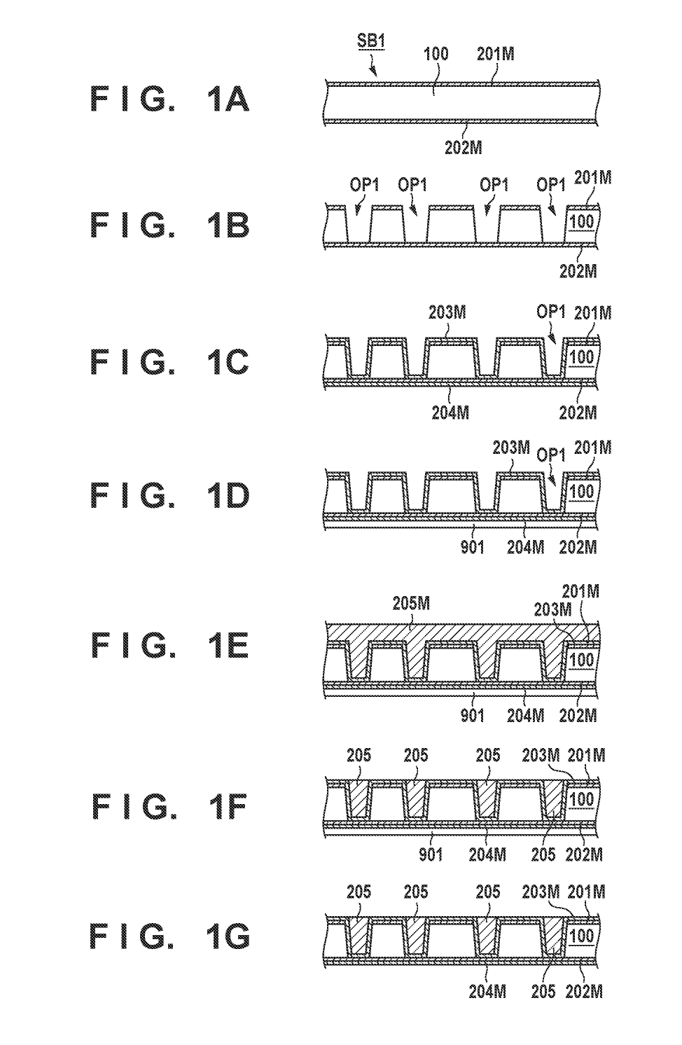

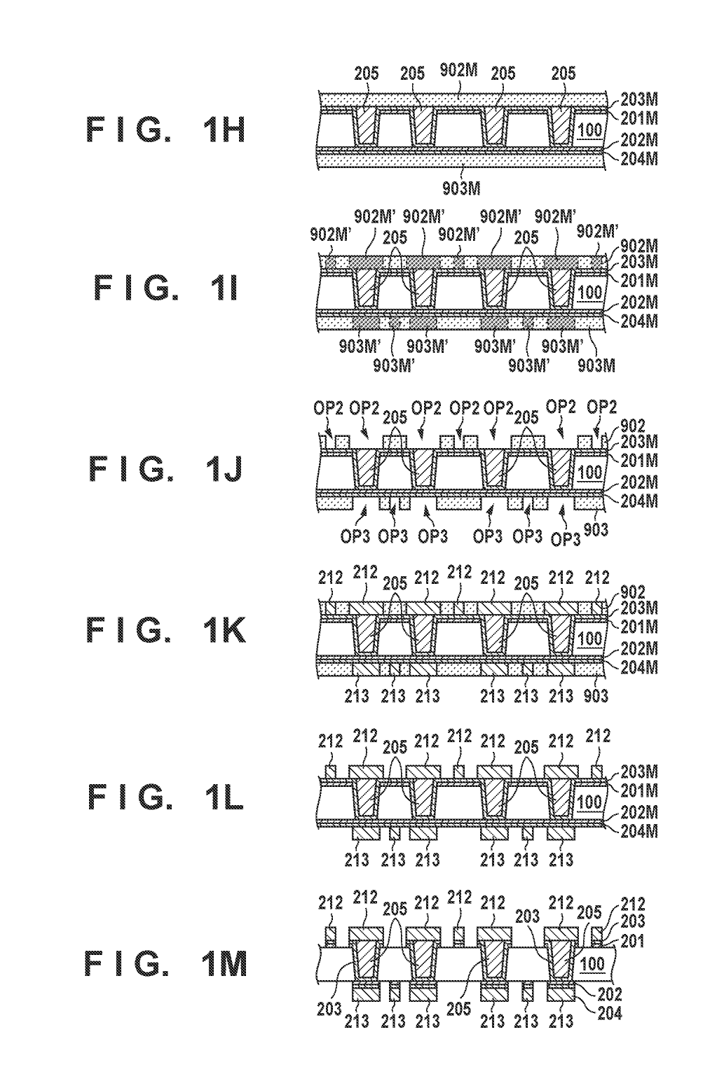

FIGS. 1A to 1M are cross-sectional views that show modes of respective processes in the method of manufacturing a flexible printed circuit board (flexible printed circuit) according to a first embodiment.

In a process shown in FIG. 1A, a substrate SB1 is prepared. The substrate SB1 includes a flexible base 100 and metal films 201M and 202M. The base 100 is made of a flexible insulating material (resin material such as polyimide, for example), which serves as a base for the printed circuit board. The base 100 may be referred to as a plate, a parent material, or the like. The metal film 201M is provided so as to cover an upper surface of the base 100. Also, the metal film 202M is provided so as to cover a lower surface of the base 100. In the present embodiment, copper is used to form the metal films 201M and 202M, but another metal material may be used. This process may be performed by forming the metal films 201M and 202M on the base 100 using a known film forming method, but another method may be used.

Note that, in this specification, the expressions such as upper surface/lower surface and upper/lower are used to indicate a relative positional relationship, and here, upper/lower are indicated based on the positional relationship in a vertical direction in the drawings (a direction vertical to the surface direction of the base 100). Also, the direction orthogonal to the vertical direction corresponds to a horizontal direction (surface direction), and in this specification, the relative positional relationship in this direction may be referred to as sideward.

In a process shown in FIG. 1B, etching is performed on the substrate SB1 using a laser, and openings OP1 are formed by removing portions of the base 100 and portions of the metal film 201M. A known laser such as a UV laser or CO₂ laser may be used as the laser for etching. In the present embodiment, the openings OP1 are formed such that an upper surface of the metal film 202M is exposed. In the present embodiment, a plurality of openings OP1 are formed, but the number of openings OP1 may be one.

In a process shown in FIG. 1C, metal films 203M and 204M are formed on the substrate SB1 obtained in the process shown in FIG. 1B (the structure obtained as the result of each process is also expressed as “substrate SB1” in order to simplify the description, which is also applied to later-described other processes) using an electroless plating method. In the present embodiment, copper films are formed by plating as the metal films 203M and 204M. The metal film 203M is formed on the upper surface side of the substrate SB1, and the metal film 204M is formed on the lower surface side of the substrate SB1.

In a process shown in FIG. 1D, a protective film 901 is formed on the lower surface of the substrate SB1 obtained in the process shown in FIG. 1C. The protective film 901 is used to regulate film formation that is performed using an electroplating method, which will be described later. The protective film 901 may be formed using a known coating method.

In a process shown in FIG. 1E, a metal member 205M is formed on the substrate SB1 obtained in the process shown in FIG. 1D using the electroplating method. In the present embodiment, a copper coating is formed as the metal member 205M. In this process, the metal film 203M acts as a seed layer, and the metal member 205M is formed on the substrate SB1 so as to cover the metal film 203M and fill the openings OP1. Note that the protective film 901 is provided on the lower side of the substrate SB1, and therefore, a metal member (copper plating) is not formed on the lower side.

In a process shown in FIG. 1F, etching of the metal member 205M is performed on the substrate SB1 obtained in the process shown in FIG. 1E, and the etching is stopped when the upper surface of the metal film 203M is exposed. With this, portions of the metal member 205M other than the portions that fill the openings OP1 are removed. The portions that fill the openings OP1 are metal pillars 205. This process is also referred to as etch-down or the like, and may be performed using a known etch-down apparatus.

In a process shown in FIG. 1G, the protective film 901 is removed from the substrate SB1 obtained in the process shown in FIG. 1F. This process may be performed using a known release agent.

In a process shown in FIG. 1H, photosensitive dry film resists 902M and 903M are respectively formed on the upper and lower sides of the substrate SB1 obtained in the process shown in FIG. 1G. The process may be performed using a known compression bonding apparatus. Note that, in the present embodiment, the dry film resists 902M and 903M are positive type resists, but one of or both of the dry film resists 902M and 903M may be a negative type resist, as another example.

In a process shown in FIG. 1I, exposure processing is performed on the substrate SB1 obtained in the process shown in FIG. 1H, and portions of the dry film resists 902M and 903M to be removed are exposed. In the present embodiment, portions in which wiring patterns will be formed later, portions located above the metal pillars 205, and the like, of the dry film resist 902M, are exposed, and the exposed portions are indicated as exposed portions 902M′ in the diagram. Similarly, portions in which wiring patterns will be formed later, portions located under the metal pillars 205, and the like, of the dry film resist 903M, are exposed, and the exposed portions are indicated as exposed portions 903M′ in the diagram.

In a process shown in FIG. 1I, the exposed portions 902M′ and 903M′ are removed by performing development processing on the substrate SB1 obtained in the process shown in FIG. 1I, and resist patterns 902 and 903 are formed. The resist pattern 902 has openings OP2 in regions in which the exposed portions 902M′ were present. Also, the resist pattern 903 has openings OP3 in regions in which the exposed portions 903M′ were present.

In a process shown in FIG. 1K, metal patterns 212 and 213 are formed on the substrate SB1 obtained in the process shown in FIG. 13 using an electroplating method. In the present embodiment, copper coatings are formed as the metal patterns 212 and 213. In this process, the metal film 203M and the metal pillar 205 act as a seed layer, and the metal pattern 212 is formed so as to fill the openings OP2 on the upper side of the substrate SB1. Also, in this process, the metal film 204M acts as a seed layer, and the metal pattern 213 is formed so as to fill the openings OP3 on the lower side of the substrate SB1.

In a process shown in FIG. 1L, the resist patterns 902 and 903 are removed from the substrate SB1 that is obtained in the process shown in FIG. 1K. This process may be performed using a known release agent.

In a process shown in FIG. 1M, metal patterns 201 to 204 are formed by removing portions of the metal films 201M to 204M by performing etching on the substrate SB1 obtained in the process shown in FIG. 1L. Here, portions of the metal films 201M to 204M that are not covered by the metal patterns 212 and 213 are removed by flash etching.

Although the details will be described later, according to the manufacturing method as described above, a flexible printed circuit board (flexible printed circuit) can be manufactured so as to include a wiring pattern having a relatively high aspect ratio.

Note that typical methods for forming a desired pattern on a substrate (or a base) include a subtractive method and an additive method. The subtractive method is a method for forming a desired pattern of a target member by partially removing (patterning) the target member that has been uniformly formed on a substrate. The additive method is a method for forming a desired pattern of a member by forming, in advance, a resist pattern in which the region where the desired pattern will be formed is exposed on a substrate, and forming the member in the exposed region. In contrast, the manufacturing method described in FIGS. 1A to 1M is referred to as a semi-additive method, and can be distinguished from the subtractive method and the additive method.

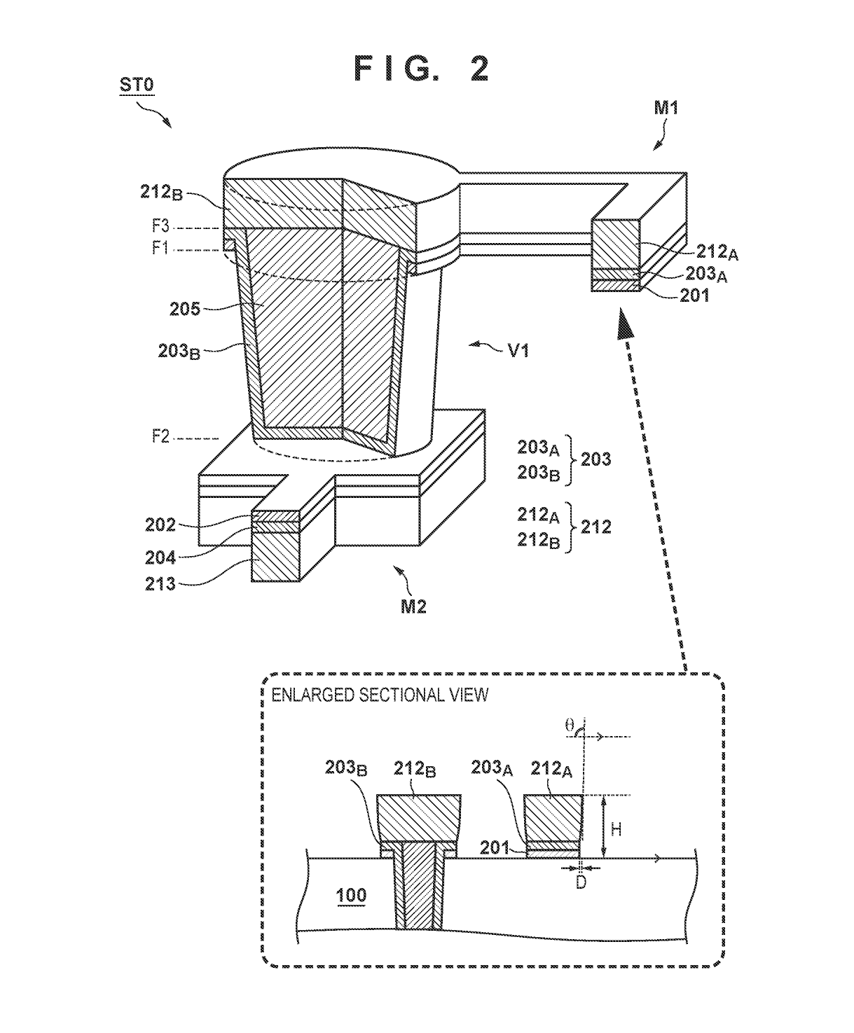

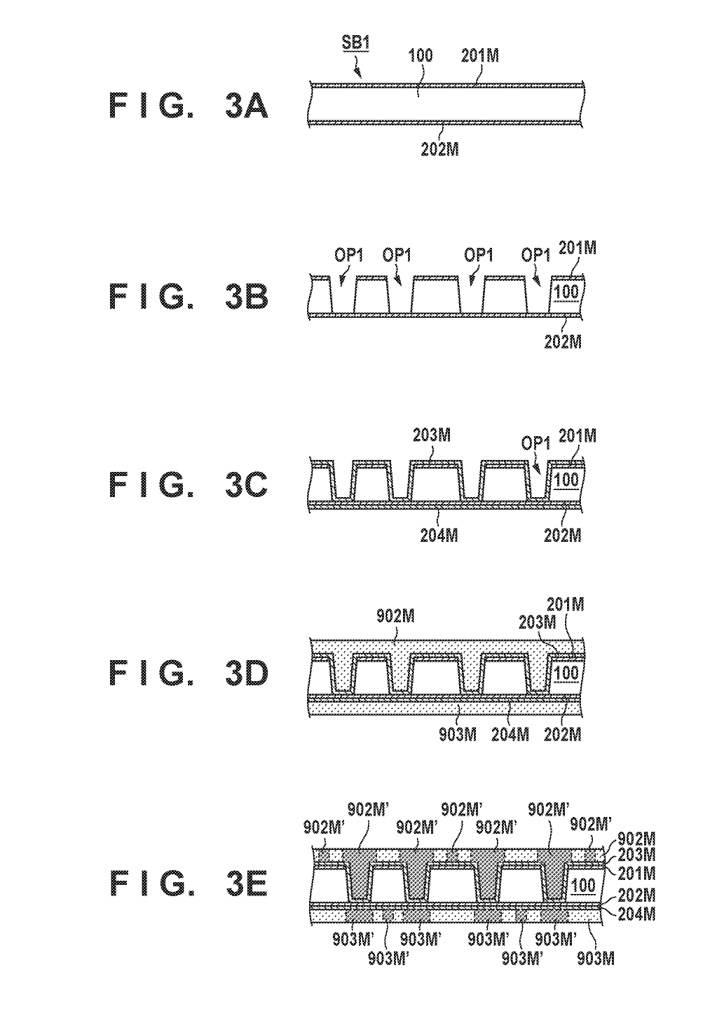

FIG. 2 is a perspective view of a wiring structure ST0 in a printed circuit board obtained using the manufacturing method described above. Here, in order to facilitate understanding of the diagram, the base 100 is not shown, and a first wiring pattern M1, a second wiring pattern M2, and a via V1 that are formed by the metal patterns 201 and the like (201 to 205, 212 and 213) are shown as the wiring structure ST0.

In other words, the printed circuit board according to the embodiment includes the wiring structure ST0. The wiring structure ST0 includes the first wiring pattern M1 that is arranged on an upper surface F1 of the base 100, the second wiring pattern M2 that is arranged on a lower surface F2 of the base 100, and the via V1 that passes through the base 100 and electrically connects the wiring patterns M1 and M2. Note that the surface F may be expressed as a surface, a principal surface, and the like, instead of the upper surface. Also, the surface F2 may be expressed as a back surface, a bottom surface, and the like, instead of the lower surface.

Here, in order to make the description easier to understand, a portion of the metal pattern 203 that extends in a horizontal direction so as to form a line pattern is denoted as a metal pattern 203_{A}, and a portion that covers a side face and a lower face (bottom face) of the metal pillar 205 is denoted as a metal film 203_{B}, in order to distinguish therebetween. Also, a portion of the metal pattern 212 that is located above the metal pattern 203_{A} is denoted as a metal pattern 212_{A}, and a portion located above the metal pillar 205 and the metal film 203_{B} is denoted as a metal pattern 212_{B}, in order to distinguish therebetween.

As is understood from the process shown in FIG. 1M (flash etching) and the like described above, the metal pattern 203_{A} is formed as an underlayer of the metal pattern 212_{A}, and the metal pattern 201 is formed as an underlayer of the metal pattern 203_{A}. Therefore, the external shapes of the metal patterns 201, 203_{A}, and 212_{A} approximately match each other in plan view (when viewed in the vertical direction).

Also, as is understood from the processes shown in FIGS. 1C, 1M, and the like, the metal film 203_{B} is formed so as to cover side faces and a lower face of the metal pillar 205 when the metal pattern 203_{A} is formed. Therefore, the metal pattern 203_{A} and the metal film 203_{B} are made of the same material, and are integrally connected.

Note that it is possible that a portion of the metal film 201M remains under an upper end portion (circumferential portion in plan view) of the metal film 203_{B}, but the process shown in FIG. 1M may be performed such that this portion does not remain, and the exposed portion 902M′ may be formed in the process shown in FIG. 1I so as to realize this structure.

The metal pattern 204 is formed as an underlayer of the metal pattern 213, the metal pattern 202 is formed as an underlayer of the metal pattern 204, and external shapes of them approximately match each other in plan view, similarly to the metal patterns 201, 203_{A}, and 212_{A}.

Note that the shapes of the metal patterns 201 and the like are not limited to those shown in the present embodiment. For example, the metal pillar 205 is illustrated as an approximately columnar shape, but may be formed to have a polygonal pillar shape such as a square pillar. Also, here, the metal pattern 212s is illustrated as an approximately circular shape in plan view, but may be formed to have a polygonal shape such as a rectangle, for example.

The via V1 includes the metal pillar 205 and the metal film 203_{B}, and is provided (extended) so as to extend in the vertical direction such that the wiring patterns M1 and M2 are connected.

The first wiring pattern M1 includes the metal patterns 201, 203_{A}, and 212. The metal patterns 201, 203_{A}, and 212_{A} are stacked in order from the surface F1 side, and the external shapes thereof approximately match each other in plan view (refer to FIGS. 1M and 2). Also, the metal pattern 212_{B} is integrally connected to the metal pattern 212_{A}, and is provided so as to have a larger width than the metal pattern 212_{A} in a portion above the metal pillar 205. With regard to the first wiring pattern M1, as a result of the metal pattern 212_{B} being brought into contact with the upper face of the metal pillar 205 and connected to the metal pillar 205 from above, the first wiring pattern M1 and the via V1 are electrically connected to each other. Note that, since the first wiring pattern M1 is formed on the metal pillar 205 after the metal pillar 205 has been formed (refer to FIG. 1F), the first wiring pattern M1 can be flattened using a relatively simple method (refer to FIG. 1K).

The second wiring pattern M2 includes the metal patterns 202, 204, and 213 that are stacked in order from the surface F2 side, and the external shapes of the metal patterns approximately match each other in plan view (refer to FIGS. 1M and 2). The second wiring pattern M2 extends to the lower face of the metal pillar 205, and is provided so as to have a larger width at the lower face. Also, the second wiring pattern M2 comes into contact with a portion of the metal film 203a that covers the lower face of the metal pillar 205, and accordingly, the second wiring pattern M2 and the via V1 are electrically connected to each other.

Note that, as is understood from FIG. 2, when the upper end surface of the metal film 203a is denoted as a surface F3, a boundary surface is formed between the metal pillar 205 and the metal pattern 212_{B} on the same plane as the surface F3. Although a detailed description will be given later, this is caused by the fact that the metal pillar 205 and the metal pattern 212_{B} are separately formed, that is, a fact that the formation processes thereof are different to each other. This boundary surface can be observed using an electron microscope or the like.

The manufacturing method of the present embodiment is realized using a known manufacturing technology. The substrate SB1 obtained in the process shown in FIG. 1M is thereafter coated by a predetermined insulating material so as to cover the wiring patterns M1 and M2, and then is transferred to a processing apparatus that performs the next process.

Note that, although copper is illustrated as the material of the metal patterns 201 and the like that form the wiring structure ST0, metal such as gold or silver and an alloy thereof may be used.

Incidentally, in accordance with the increase in the density of the wiring structure ST0, the width and the pitch of the wiring patterns M1 and M2 of the printed circuit board need to be reduced. The first wiring pattern M1 (and also the second wiring pattern M2) can be formed to have a relatively high aspect ratio (the ratio obtained by dividing the wiring height by the wiring width, here) in order to suppress the increase in resistance due to the reduction in width.

For example, the width of the wiring pattern M1 is preferably 50 μm or less, more preferably 30 μm or less, and further preferably 10 μm or less. Also, when a plurality of the wiring patterns M1 are formed in parallel, the plurality of wiring patterns M1 are formed to have similar pitches (preferably 50 μm or less, more preferably 30 μm or less, and even more preferably 10 μm or less). Here, the height of the wiring pattern M1 is preferably 6 μm or more, more preferably 10 μm or more, and even more preferably 20 μm or more. With regard to the aspect ratio, an aspect ratio of at least 0.7 or more, preferably 1.0 or more, and more preferably 2.0 or more can be realized. In the wiring structure ST0 according to the present embodiment, the wiring patterns M1 and M2 can each be formed to have a width in a range from 2 μm to 50 μm, and a height in a range from 6 μm to 35 μm.

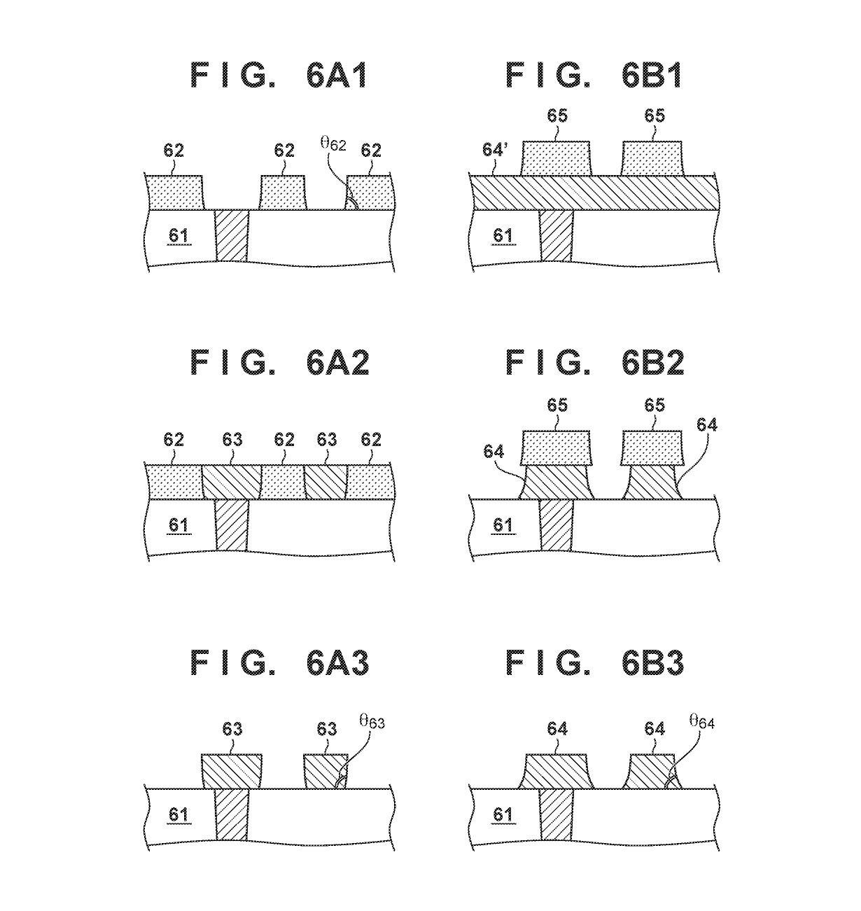

According to the present embodiment, the wiring patterns M1 and M2 can be approximately vertically formed, and the present embodiment is advantageous for forming the wiring patterns M1 and M2 having a relatively high aspect ratio. The reason will be described in detail with reference to FIG. 6A1 and the like. FIGS. 6A1, 6A2, and 6A3 are schematic diagrams for illustrating the shapes of wiring patterns corresponding to the processes shown in FIGS. 1J, 1K, and 1L, respectively.

In the process shown in FIG. 6A1, patterning of a resist member formed on a substrate 61 is performed by exposure processing and development processing, and a photoresist pattern 62 is formed. Therefore, in general, the photoresist pattern 62 can be formed to have a shape in which side faces are inclined and curved in a concave shape. Also, the angle (interior angle) 0& between each side face and a corresponding lower face of the photoresist pattern 62 is at least not an obtuse angle, and may be in a range 75°<θ₆₂<90°, for example. In the process shown in FIG. 6A2, a wiring pattern 63 is formed so as to fill openings of the photoresist pattern 62. Here, the side faces of the wiring pattern 63 are formed so as to be conformable with the side faces of the photoresist pattern 62. Thereafter, the photoresist pattern 62 is removed in a process shown in FIG. 6A3.

According to such a forming method, the wiring pattern 63 is formed so as to be conformable with the shape of the photoresist pattern 62 such that the side faces are curved in a convex shape. Also, the angle θ63 between each face and a corresponding lower face can be in a range of 90°<θ₆₃<105°. Note that the angle θ₆₃ may be referred to as an angle of inclination of side faces of the wiring pattern 63.

On the other hand, as a reference example, FIGS. 6B1, 6B2, and 6B3 show schematic diagrams for illustrating the shape of a wiring pattern 64, when the wiring pattern 64 is formed by performing patterning on a metal member 64′ formed on the substrate 61.

In the process shown in FIG. 6B1, a photoresist pattern 65 is formed on a metal member 64′ that has been formed on the substrate 61. In a process shown in FIG. 6B2, etching is performed on the metal member 64′ using the photoresist pattern 65 as a mask. Accordingly, exposed portions of the metal member 64′ (portions that are not covered by the photoresist pattern 65) are removed, and the wiring pattern 64 is formed. Thereafter, the photoresist pattern 65 is removed in a process shown in FIG. 6B3.

Here, in the process shown in FIG. 6B2, etching of the metal member 64′ advances, in general, not only in the vertical direction (downward in the diagram), but also in the horizontal direction. Therefore, the etched amount in the horizontal direction may increase in an upper portion of the metal member 64′ than in a lower portion. Therefore, in the wiring pattern 64 formed in this way, the angle θ₆₄ between each side face and a corresponding lower face is at least an acute angle (about 70°<θ₆₄<90°, or θ₆₄<70°, for example), and the side faces are curved in a concave shape. In this reference example, the evaluation value (so-called etching factor) of etching accuracy, which is obtained by dividing the etching amount in the vertical direction by the etching amount in the horizontal direction, is about 3.5 (θ₆₄ is about 74°). This phenomenon becomes prominent when the height (thickness) of the wiring pattern 64 increases, and may be a factor that makes it difficult to increase the density of the wiring structure. Note that the angle θ₆₄ may be referred to as an angle of inclination of the side faces of the wiring pattern 64.

In summary, the shape of the side faces of the wiring pattern 64 obtained in the processes shown in FIGS. 6B1 to 6B3 (corresponding to the reference example) depends on the accuracy of patterning the metal member 64′ by etching, which is mainly determined by the directivity of etching solution/gas. In contrast, the shape of the side faces of the wiring pattern 63 obtained in the processes in FIGS. 6A1 to 6A3 (corresponding to the present embodiment) depends on the shape of the resist pattern 62, that is, the accuracy of patterning the resist member by exposure processing and development processing, which is mainly determined by the directivity of exposure light. Therefore, in general, the wiring pattern 64 corresponding to the reference example can be formed to have a shape in which the side faces are curved in a concave shape and are relatively inclined. In contrast, the wiring pattern 63 corresponding to the present embodiment can be formed to have a shape in which the side faces are curved in a convex shape and are relatively vertical. When the angle of inclination θ₆₄ of the side faces of the wiring pattern 64 corresponding to the reference example and the angle of inclination θ₆₃ of the side faces of the wiring pattern 63 corresponding to the present embodiment are compared, |θ₆₃−90°|<|θ₆₄−90°| is satisfied. That is, the wiring pattern 63 obtained using the method shown in FIGS. 6A1 to 6A3 can have approximately vertical side faces, and it can be said that it is advantageous for increasing the aspect ratio, and for increasing the wiring height.

The method shown in FIGS. 6A1 to 6A3 corresponds to the additive method described above, the method shown in FIGS. 6B1 to 6B3 corresponds to the subtractive method described above. In the present embodiment (that is, a semi-additive method in which an electroplating method is performed using the metal film 203M as a seed layer), the aspect ratio similar to that shown in FIGS. 6A1 to 6A3 or more can be realized.

Referring to FIG. 2 again, as is understood from an enlarged cross-sectional view of the first wiring pattern M1, according to the present embodiment, the first wiring pattern M1 can be formed to have an approximately vertical side faces. As described above, in the present embodiment, the metal patterns 201 and 203 are formed by patterning the metal films 201M and 203M with flash etching in the process shown in FIG. 1M. The film thicknesses of the metal films 201M and 203M are relatively small, and are several microns, for example, and therefore, the side faces of the metal patterns 201 and 203 are approximately vertical (substantially not inclined). Therefore, in the wiring pattern M1, the angle (angle of inclination) θ between at least a portion of (most of, in the present embodiment) each side face and the surface F1 satisfies 90°<θ<105°. As shown in the enlarged cross-sectional view in FIG. 2, the angle of inclination θ is an angle between a tangential direction directed upward at an arbitrary point on a side face of the wiring pattern M1 and the horizontal direction directing inward of the wiring pattern M1 from that point. In other words, the width of the wiring pattern M1 in the horizontal direction increases from the lower side toward the upper side, and the side faces have a reversed tapered shape in which the angle of inclination θ is in a range of 90°<θ<105°.

Here, as a method of evaluating the patterning accuracy corresponding to the aforementioned etching factor, the height from the lower face to the upper face of the wiring pattern M1 is denoted as H, and the distance from the end of the lower face to the end of the upper face of the wiring pattern M1 in the horizontal direction is denoted as D, for example. Here, it is preferable that H/D≤5 (θ is about 101°) is satisfied. It is more preferable that H/D≥10 (θ is about 96°) is satisfied, that is, with regard to the angle of inclination θ, it is more preferable that 90°<θ≤100 is satisfied. It is even more preferable that H/D≥15 (θ is about 940) is satisfied, that is, with regard to the angle of inclination θ, it is more preferable that 90°<θ≤95° is satisfied.

Note that above discussion using the angle of inclination θ and H/D can be applied to a cross section in any plane orthogonal to the extending direction of the wiring pattern M1, and can also be applied to a cross section of the metal pattern 212_{B} that passes through the center of the metal pillar 205. Also, the same applies to the second wiring pattern M2.

As described above, the method according to the present embodiment is specifically advantageous when the wiring pattern M1 having a relatively large aspect ratio and a relatively large wiring height is formed, and accordingly, the increase in the resistance of the wiring pattern M1 can be suppressed.

The flexible printed circuit board (flexible printed circuit) according to the present embodiment is used for connecting two or more electronic components, and the present embodiment can be preferably applied to an electronic device including them. For example, it is also possible that a semiconductor package such as a BGA package or a QFP package, as an example of the electronic component, is mounted on an FPC to form a so-called COF (chip on film). This similarly applies to later-described embodiments.

### Second Embodiment

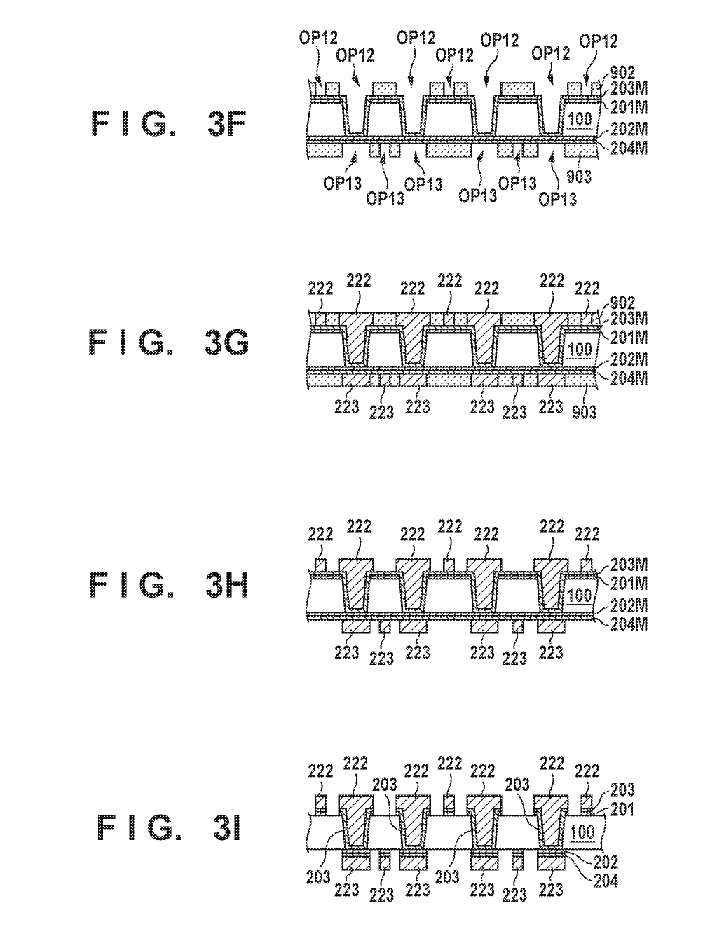

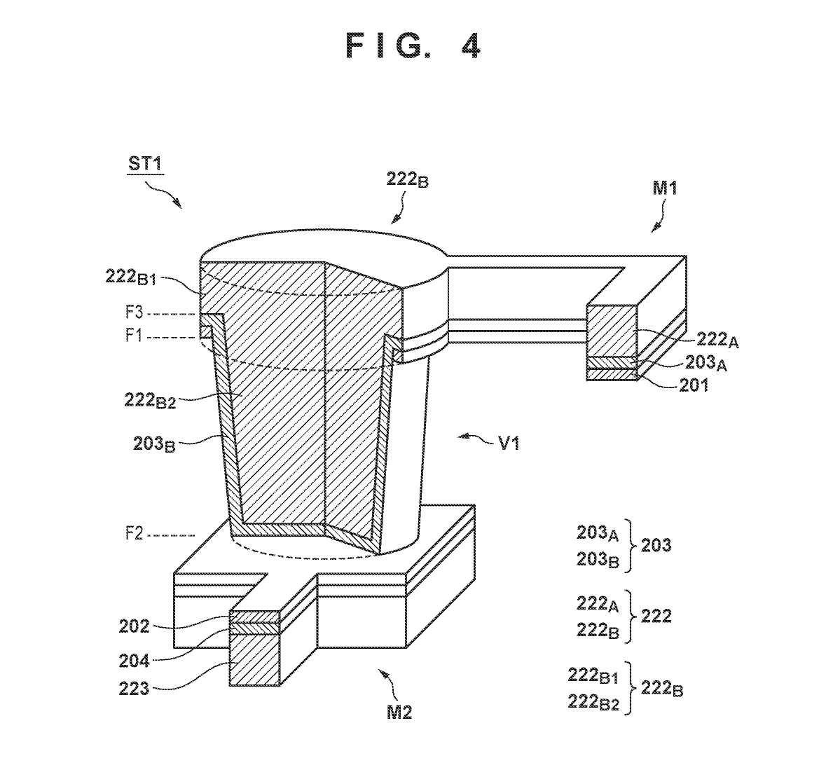

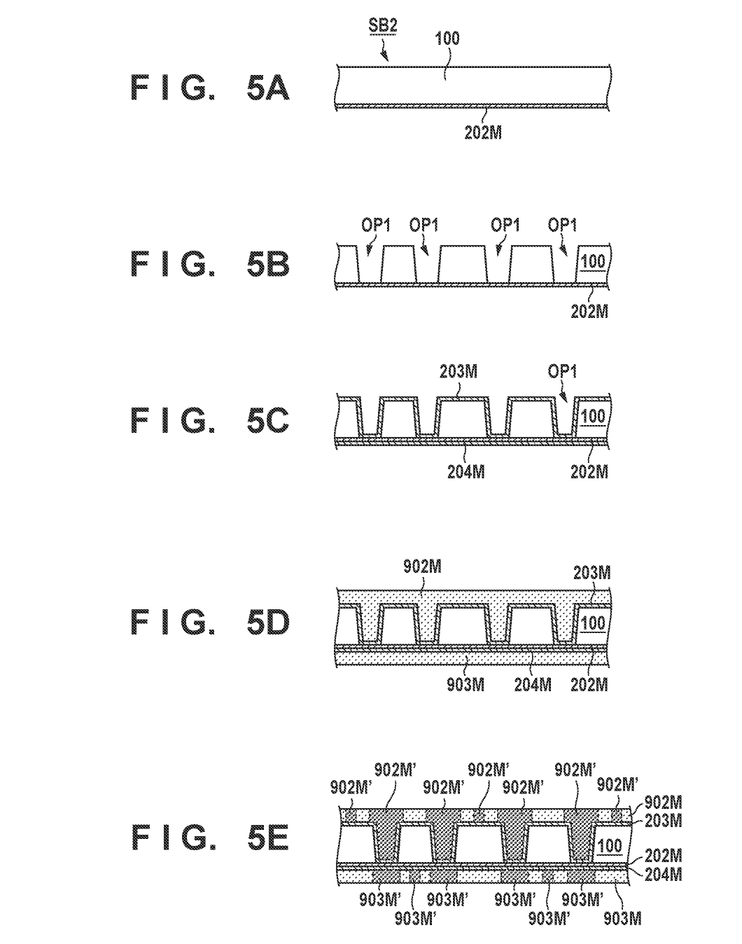

FIGS. 3A to 3I are cross-sectional views illustrating modes of respective processes in the manufacturing method of a printed circuit board according to a second embodiment. The manufacturing method according to the present embodiment can be realized using a known manufacturing technology, similarly to the above-described first embodiment. The processes shown in FIGS. 3A to 3C are similar to the processes shown in FIGS. 1A to 1C in the first embodiment, and therefore, the description thereof will be omitted.

In a process shown in FIG. 3D, dry film resists 902M and 903M are respectively formed on the upper and lower sides of the substrate SB1 obtained in the process shown in FIG. 3C. This process may be performed using the procedure similar to the process shown in FIG. 1H. Note that the dry film resist 902M need only be formed so as to fill the openings OP1 or seal the inside of each opening OP1, and the inside of each opening OP1 need not be completely filled with the dry film resist 902M.

In a process shown in FIG. 3E, portions of the dry film resists 902M and 903M to be removed are exposed by performing exposure processing on the substrate SB1 obtained in the process shown in FIG. 3D, and exposed portions 902M′ and 903M′ are formed. This process may be performed using a procedure similar to the process shown in FIG. 1I. Here, the portions of the exposed portions 902M′ that fill the openings OP1 may be sufficiently exposed to the inside of the openings OP1 so as to be appropriately removed in the later-described development processing.

In a process shown in FIG. 3F, the exposed portions 902M′ and 903M′ are removed by performing development processing on the substrate SB1 obtained in the process shown in FIG. 3E, and accordingly, resist patterns 902 and 903 are formed. The process may be performed using a procedure similar to the process shown in FIG. 1J. The resist pattern 902 has a shape in which openings OP12 are included in regions where the exposed portion 902M′ were present. Also, the resist pattern 903 has a shape in which openings OP13 are included in regions where the exposed portion 903M′ were present.

In a process shown in FIG. 3G, metal patterns 222 and 223 are formed on the substrate SB1 obtained in the process shown in FIG. 3F using an electroplating method. This process may be performed using a procedure similar to the process shown in FIG. 1K, and copper patterns are formed by plating as the metal patterns 222 and 223. The metal pattern 222 is formed on the upper side of the substrate SB1 so as to fill the openings OP12. Also, the metal pattern 223 is formed on the lower side of the substrate SB1 so as to fill the openings OP13.

In a process shown in FIG. 3H, the resist patterns 902 and 903 are removed from the substrate SB1 obtained in the process shown in FIG. 3G. The process may be performed using a procedure similar to the process shown in FIG. 1L.

In a process shown in FIG. 3I, portions of the metal films 201M to 204M that are not covered by the metal pattern 222 or the metal pattern 223 are removed by performing etching (flash etching) on the substrate SB1 obtained in the process shown in FIG. 3H. Accordingly, the metal patterns 201 to 204 are formed. The process may be performed using a procedure similar to the process shown in FIG. 1M.

FIG. 4 is a perspective view of a wiring structure ST1 in a printed circuit board obtained using the manufacturing method described above. A first wiring pattern M1, a second wiring pattern M2, and a via V1 that are formed by the metal patterns 201 and the like are shown as a wiring structure ST1, similarly to the first embodiment. The present embodiment mainly differs from the first embodiment in that a portion of the first wiring pattern M1 and a portion of the via V1 are integrally provided.

Here, “integrally” in this specification refers to a mode in which portions are integrally formed using a single member. Therefore, when two portions are integrally formed, no boundary surface therebetween can be seen. The boundary surface can be observed using an electron microscope or the like. If two portions are separately formed in different processes, a boundary surface is formed, in general, even if the same material is used.

Here, in order to simplify the description, a portion of the metal pattern 222 located above a metal pattern 203_{A} is denoted as a metal pattern 222_{A}, and a portion that is surrounded by a metal film 203_{B} and extends in the vertical direction is denoted as a metal pillar 222_{B} so as to distinguish therebetween. Note that the metal pattern 203_{A} and the metal film 203_{B} are similar to those in the first embodiment.

As is understood from the process shown in FIG. 3I (flash etching) and the like described above, the metal pattern 203_{A} is formed as an underlayer of the metal pattern 222_{A}, and the metal pattern 201 is formed as an underlayer of the metal pattern 203_{A}. Therefore, similarly to the first embodiment, the external shapes of the metal patterns 201, 203_{A}, and 222_{A} approximately match to each other in plan view. Also, similarly to the first embodiment, the metal film 203_{B} is formed along with the formation of the metal pattern 203_{A} (refer to FIGS. 3C, 3I, and the like), and the metal film 203_{B} is made of the same material as the metal pattern 203_{A}.

Similarly to the metal patterns 201, 203_{A}, and 222_{A}, the metal pattern 204 is formed as an underlayer of the metal pattern 223, the metal pattern 202 is formed as an underlayer of the metal pattern 204, and the external shapes thereof approximately match to each other in plan view.

In the present embodiment, the via V1 includes the metal pillar 222_{B} and the metal film 203_{B}. The first wiring pattern M1 includes the metal patterns 201, 203_{A}, and 222_{A} that are stacked in order from a surface F side. Also, the second wiring pattern M2 includes the metal patterns 202, 204, and 223 that are stacked in order from a surface F2 side.

With regard to the relation with the first embodiment (wiring structure ST0) described above (refer to FIGS. 1M, 2, and the like), the metal pattern 222_{A} in the present embodiment corresponds to the portion 212_{A}, of the metal pattern 212 in the first embodiment, that is immediately above the metal patterns 201 and 203. Also, the metal pattern 223 in the present embodiment corresponds to the metal pattern 213 in the first embodiment. On the other hand, the metal pillar 222_{B} in the present embodiment corresponds to the metal pillar 205 in the first embodiment, and also corresponds to the portion 212_{B}, of the metal pattern 212 in the first embodiment, which is immediately above the metal pillar 205. That is, the metal pillar 222_{B} in the present embodiment can also be said to correspond to the portion obtained by integrating the metal pillar 205 and the wiring pattern 212_{B} in the first embodiment. Note that the discussion of the angle of inclination θ, and H/D about the wiring structure ST0 in the first embodiment can be similarly applied to the wiring structure ST1 in the present embodiment.

As is also understood from FIG. 4, the metal pillar 222_{B} is integrally provided so as to extend from below to the above of the surface F1, that is, the metal pillar 222_{B} is formed by a single member so as to protrude/extend above the surface F1. Here, the first wiring pattern M1 is formed on the surface F1. Therefore, the metal pillar 222_{B} is formed by a single member so as to protrude to the height at which the first wiring pattern M1 is formed, that is, to the position of the wiring layer.

In order to give a detailed description, the upper portion of the metal pillar 222_{B} is denoted as a pillar upper portion 222_{B1}, and the lower portion thereof is denoted as a pillar lower portion 222_{B2} so as to distinguish therebetween. The pillar upper portion 222_{B1} corresponds to at least a portion above the surface F1, and may be a portion above the upper end surface (boundary surface between the first metal pattern 222_{A} and the second metal pattern 203_{A} that are stacked) F3 of the metal film 203_{B}, for example. The pillar lower portion 222_{B2} corresponds to a portion below the pillar upper portion 222_{B1}, and may be a portion covered by the metal film 203_{B}, or a portion surrounded by the base 100, for example.

In the present embodiment, the first wiring pattern M1 has a shape in which the first wiring pattern M1 is connected to the pillar upper portion 222_{B1} from the side (in the horizontal direction), and the metal pattern 222_{A} of the first wiring pattern M1 is integrally connected to the pillar upper portion 222_{B1} from the side.

Incidentally, in accordance with the increase in the density of the wiring structure ST1, and the reduction in the width of the wiring patterns M1 and M2 of the printed circuit board, it is required that the electrical connection between the wiring patterns M1 and M2 with the via V1 is appropriately realized. As described in the first embodiment, the first wiring pattern M1 (the second wiring pattern M2 also) can be formed so as to have a relatively high aspect ratio in order to suppress the increase in the resistance due to the reduction in the width.

Also, in accordance with the reduction in the width of the wiring pattern M1, the diameter of the via V1 may need to be reduced. As described above, in the case of the wiring structure ST0 in the first embodiment (refer to FIG. 2), a boundary surface is formed between the metal pillar 205 and the metal pattern 212_{B}. Therefore, when the wiring pattern M1 (wiring width: about 2 μm to 50 μm) as in the first embodiment is considered, it is possible that, as the diameter of the via V1 decreases, a connection failure occurs between the metal pillar 205 and the metal pattern 212_{B} due to the boundary surface that exists therebetween. This connection failure includes, in addition to a case where two conductive members are in a non-conductive state, a case where an unexpected resistance component is generated therebetween.

According to the wiring structure ST1 of the present embodiment, the metal pillar 222_{B} has a shape in which the metal pillar 222_{B} is formed by a single member so as to protrude above the surface F1 (to the position of the wiring layer), and the wiring pattern M1 is connected to the pillar upper portion 222_{B1}, which is an upper portion of the metal pillar 222_{B}, from the side, as described above. Therefore, according to the present embodiment, the electrical connection between the wiring pattern M1 and the via V1 can be appropriately realized without causing a connection failure at the via V1, and therefore, the reliability of the printed circuit board can be improved.

Also, in the present embodiment, the metal pattern 222_{A} of the wiring pattern M1 and the metal pillar 222_{B} are formed at the same time in the same process (refer to FIGS. 3C and 3I). Also, as a result of the metal pillar 222_{B} being formed by a single member so as to protrude above the surface F3, the metal pattern 222_{A} is integrally connected to the pillar upper portion 222_{B1} of this metal pillar 222_{B} from the side (refer to FIG. 4). Therefore, the present embodiment is advantageous for reducing manufacturing costs, because the number of manufacturing steps can be reduced, in addition to the connection failure being suppressed/reduced.

Also, in the present embodiment, the metal pillar 222_{B} is substantially entirely covered by the metal film 203_{B} at the side and lower faces of the pillar lower portion 222_{B2}, and the metal film 203_{B} is appropriately connected to the second wiring pattern M2. As a result, the wiring patterns M1 and M2 are appropriately electrically connected without causing a connection failure between the pattern M2 and the via V1.

### Third Embodiment

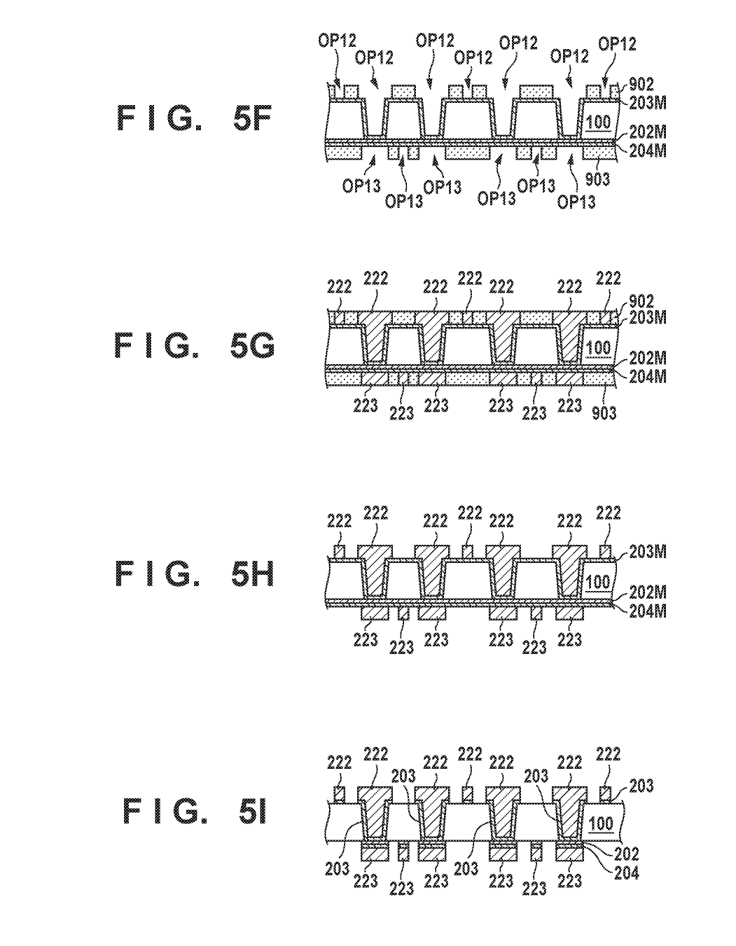

The present invention is not limited to the structures described in the first and second embodiments, and various types of modifications can be applied, and a wiring layer or a wiring pattern may be added/removed as necessary. FIGS. 5A to 5I show modes in respective processes in the manufacturing method of a printed circuit board according to a third embodiment, as a modification of the second embodiment. The processes shown in FIGS. 5A to 5I are similar to the processes shown in FIGS. 3A to 3I (second embodiment), and therefore, the detailed description of the respective processes will be omitted.

In the present embodiment, a substrate SB2 that does not include the metal film 201M is prepared, instead of the substrate SB1. Even if such a substrate SB2 is used, a flexible printed circuit board (flexible printed circuit) can be manufactured. The present embodiment can also achieve the same effects similar to those in the second embodiment.

Also, since the substrate SB2 does not include the metal film 201M in the process shown in FIG. 5A, the substrate SB2 can be prepared at a relatively low cost. Also, in the process shown in FIG. 5B, since the metal film 201M is not present on the upper surface of a base 100, openings OP1 can be easily formed in the base 100, and therefore, the manufacturing time can be reduced. Note that, in the process shown in FIG. 5C, a metal film 203M is formed using an electroless plating method, and the processes thereafter can be executed similarly to the first embodiment. Also, according to the present embodiment, when a printed circuit board is manufactured as the FPC, since the metal film 201M is omitted, the film thickness of the first wiring pattern M1 is reduced and the structure can be simplified, and as a result, this printed circuit board can easily have preferable flexibility.

Also, if a substrate SB2 made of a flexible insulating material (resin material such as polyimide, for example) is used in the process shown in FIG. 5A, the flatness (based on JIS B0621) of the upper surface (upper surface that is not covered by the metal film 201M) tends to relatively decrease. Therefore, if a first wiring pattern M1 is formed so as to have a relatively high aspect ratio using a subtractive method or an additive method, it is conceivable that exfoliation of the formed first wiring pattern M1 occurs. On the other hand, according to the present embodiment (that is, a semi-additive method in which an electroplating method is executed using the metal film 203M as a seed layer), the first wiring pattern M1 can be appropriately formed on the metal film 203M serving as a seed layer, and therefore, it can be said that it is advantageous for improving the quality of the printed circuit board, for example. Note that the flatness can be specified using a probe scanning method, or may be evaluated using a surface roughness (Ra) that can be specified using optical interferometry.

When the surface roughness (Ra) decreases (unevenness on the surface decreases), wiring having higher aspect ratio can be provided. For example, the surface roughness (Ra) in the present embodiment is about 0.02 μm, but the surface roughness (Ra) may preferably be 0.15 μm or less, more preferably be 0.07 μm or less, as another embodiment. Also, the surface roughness (Ra) needs only be 0.001 μm or more, but may be 0.01 μm or more.

In addition, various modifications are possible, as appropriate. For example, in the embodiments described above, a structure (double layer wiring structure having two wiring layers) in which the wiring pattern M1 is arranged on the upper surface F1 side of the base 100, and the wiring pattern M2 is arranged on the lower surface F2 side of the base 100 has been illustrated. Also, the via V1 is a so-called through electrode so as to pass through the base 100 between the surfaces F1 and F2 such that the wiring patterns M1 and M2 are connected. However, a multi-layer wiring structure in which the number of wiring layers is three or more can be realized by further adding one or more wiring layers, for example.

In the case of a triple-layer wiring structure in which the number of wiring layers is three, as an example, another wiring pattern (referred to as a wiring pattern M3) is included inside the base 100 as an intermediate layer between the wiring patterns M1 and M2. In this case, another via (referred to as a via V2) may further be provided in the base 100 so as to connect this wiring pattern M3 and the wiring pattern M1 (or M2), in addition to the via V1 that connects the wiring patterns M1 and M2. The forming method and the structure of the via V1 described in the embodiments can also be applied to this via V2.

### OTHERS

Some preferable embodiments have been illustrated above, but the present invention is not limited to these examples, and portions thereof may be modified without departing from the spirit of the invention. Also, the individual terms recited herein are merely used for the purpose of describing the present invention, and the invention is not intended to be limited to a strict interpretation of the meaning of those terms, and can also include equivalents thereof. For example, the wiring pattern M1 (or M2) may be expressed as a conductive pattern, a line pattern, or the like. Also, the via V1 may be expressed as a conductive pillar, a plug, or the like

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2017-233610, filed Dec. 5, 2017, No. 2017-233611, filed Dec. 5, 2017, and No. 2018-223937, filed Nov. 29, 2018, which are hereby incorporated by reference herein in their entirety.

What is claimed is:

1. A flexible printed circuit comprising:
a flexible base;
a wiring pattern arranged on the flexible base; and
a via that is provided in the flexible base and is electrically connected to the wiring pattern,
wherein the wiring pattern is formed to have an aspect ratio of at least 0.7 or more.

2. The flexible printed circuit according to claim 1, wherein, in a cross section orthogonal to a direction in which the wiring pattern extends, the width of the wiring pattern in a horizontal direction increases from a lower side toward an upper side, and the wiring pattern includes a portion that satisfies, when the angle of inclination of a side face of the wiring pattern is denoted as θ, 90°<θ<105°.

3. The flexible printed circuit according to claim 2, wherein the portion of the side face of the wiring pattern is curved in a convex shape.

4. The flexible printed circuit according to claim 2, wherein 90°<θ≤100° is further satisfied.

5. The flexible printed circuit according to claim 2, wherein the wiring pattern is formed to have a width in a range from 2 μm to 50 μm and a height in a range from 6 μm to 35 μm.

6. The flexible printed circuit according to claim 2, wherein when, in the cross section, the height from a lower face to an upper face of the wiring pattern is denoted as H, and the distance from an end of the lower face to an end of the upper face of the wiring pattern in a horizontal direction is denoted as D, H/D≥5 is satisfied.

7. The flexible primed circuit according to claim 6, wherein H/D≥10 is further satisfied.

8. The flexible printed circuit according to claim 1,
wherein the via includes a metal pillar, and
the wiring pattern includes a portion that is connected to the metal pillar from above the metal pillar.

9. The flexible printed circuit according to claim 8, wherein a boundary surface is formed between the metal pillar and the portion of the wiring pattern.

10. The flexible printed circuit according to claim 1,
wherein the via includes a metal pillar that is integrally provided so as to extend from below an upper surface of the flexible base to above the upper surface, and
the wiring pattern is connected to a pillar upper portion, which is an upper portion of the metal pillar, from a side of the pillar upper portion.

11. The flexible printed circuit according to claim 10, wherein the wiring pattern includes, as its portion, a metal pattern that is integrally connected to the pillar upper portion from a side of the pillar upper portion.

12. The flexible printed circuit according to claim 11,
wherein the wiring pattern further includes, the metal pattern being a first metal pattern, a second metal pattern, which is an underlayer of the first metal pattern, and
the metal pillar is integrally provided so as to extend from below a boundary surface between the first metal pattern and the second metal pattern to above the boundary surface.

13. The flexible printed circuit according to claim 12, wherein the first metal pattern is made of the same material as the second metal pattern.

14. The flexible printed circuit according to claim 12,
wherein the via further includes a metal film that covers a side face of the metal pillar, and
the metal film is made of the same material as the second metal pattern.

15. The flexible printed circuit according to claim 1, further comprising, the wiring pattern being a first wiring pattern, a second wiring pattern that is arranged on a lower face of the flexible base,
wherein the via electrically connects the first wiring pattern and the second wiring pattern.

16. An electronic device comprising:
the flexible printed circuit according to claim 1; and
an electronic component to which the flexible printed circuit is connected.
